(19) United States
(12) Patent Application Publication
(10) Pub. No.: US 2005/0068275 A1
(43) Pub. Date: Mar. 31, 2005

(54) Driver circuit, as for an OLED display

(76) Inventor: Michael Gillis Kane, Skillman, NJ (US)

Correspondence Address: DANN, DORFMAN, HERRELL & SKILLMAN, P.C., SARNOFF CORPORATION, 1601 MARKET STREET, SUITE 720, PHILADELPHIA, PA, 19103, US

(21) Appl. No.: 10/926,521

(22) Filed: Aug. 26, 2004

Related U.S. Application Data
(60) Provisional application No. 60/507,060, filed on Sep. 29, 2003.

(51) Int. Cl. G11C 11/34; G11C 16/06; G09G 3/32

(52) U.S. Cl. 345/82

(57) ABSTRACT

An electronic driver circuit for driving a load exhibiting a capacitance comprises a controllable current source for providing at an output current related to an input data signal and a capacitance coupled between the output and input of the controllable current source for providing positive feedback.

This Application claims the benefit of U.S. Provisional Application Ser. No. 60/507,060 filed Sep. 29, 2003.

The present invention relates to an electronic circuit, and in particular to an electronic circuit for providing an electrical signal to a load.

“Driver circuit” is a term generally used to refer to an electronic circuit that provides an electrical signal, often referred to as “drive,” to another circuit or device, which may be referred to as a load. The “drive” may be from a driving source that approximates a voltage source (e.g., a relatively low impedance source) or may be from a driving source that approximates a current source (e.g., a relatively high impedance source), or may be from a source having a finite, non-zero impedance. Transistors in certain configurations may exhibit a relatively high output impedance and so tend to approximate a current source.

Among the many different types of typical loads are displays comprising a plurality of display elements or picture elements. The elements of a high resolution display are typically arranged in rows and columns of a display that is driven via row lines and column lines. Row lines are electrical conductors connecting to picture elements in a given row and column lines are electrical conductors connecting to picture elements in a given column. Each element is addressed and energized responsive to signals selectively applied to the row and column lines, which sometimes may be referred to as select lines and data lines, respectively. Each element is selectively actuated or energized by the electrical signals applied to the row and column lines, and is typically a light-emitting element or a light transmissive element or a light reflecting element. Applying electrical signals to a given row line and a given column line activates or energizes the light-emitting element at the intersection thereof.

Among typical displays are organic light-emitting diode (OLED) displays. All passive-matrix organic light-emitting diode (PMOLED) displays known to the inventor and some active-matrix OLED (AMOLED) displays employ current-drive on the data lines, but current drive from a fixed current source is slow to charge the large capacitance associated with the data line, and this slowness limits the resolution that may be obtained from such display.

In OLED displays: the column data line typically has a large capacitance, e.g., a few nanofarads (nF) for PMOLED displays, due to the overlap of the column line conductor with many row line conductors, with only a thin (˜100 nm) organic film separating them at each intersection. Large capacitances are very slow to charge when driven from a current source. In particular, if a current source is sourcing a current I into a capacitance C, then the time t required to charge the capacitance through a voltage swing ΔV is directly proportional to the product of the capacitance and the voltage change, divided by the charging current. As OLED efficiencies improve thereby reducing the required level of drive current, and/or if external capacitance from connectors is added, the slow-charging problem becomes worse.

Accordingly, there is a need for an electronic circuit suitable for driving a load having a capacitance associated therewith.

To this end, an electronic driver circuit may comprise a controllable current source for providing at an output current related to an input data signal and a capacitance coupled between the output and input of the controllable current source for providing positive feedback.

### BRIEF DESCRIPTION OF THE DRAWING

The detailed description of the preferred embodiment(s) will be more easily and better understood when read in conjunction with the FIGURES of the Drawing which include:

FIG. 1 is an electrical circuit schematic diagram of an example embodiment of an electronic driver circuit;

FIG. 2 is an electrical circuit schematic diagram of an example embodiment of an electronic driver circuit;

FIG. 3 is a graphical representation illustrating example voltage versus time responses for two different electronic circuits; and

FIG. 4 is an electrical circuit schematic diagram of an example embodiment of an electronic driver circuit.

In the Drawing, where an element or feature is shown in more than one drawing figure, the same alphanumeric designation may be used to designate such element or feature in each figure, and where a closely related or modified element is shown in a figure, the same alphanumerical designation primed or designated “a” or “b” or the like may be used to designate the modified element or feature. Similarly, similar elements or features may be designated by like alphanumeric designations in different figures of the Drawing. It is noted that, according to common practice, the various features of the drawing are not to scale, and the dimensions of the various features are arbitrarily expanded or reduced for clarity, and any value stated in any Figure is given by way of example only.

### DESCRIPTION OF THE PREFERRED EMBODIMENT(S)

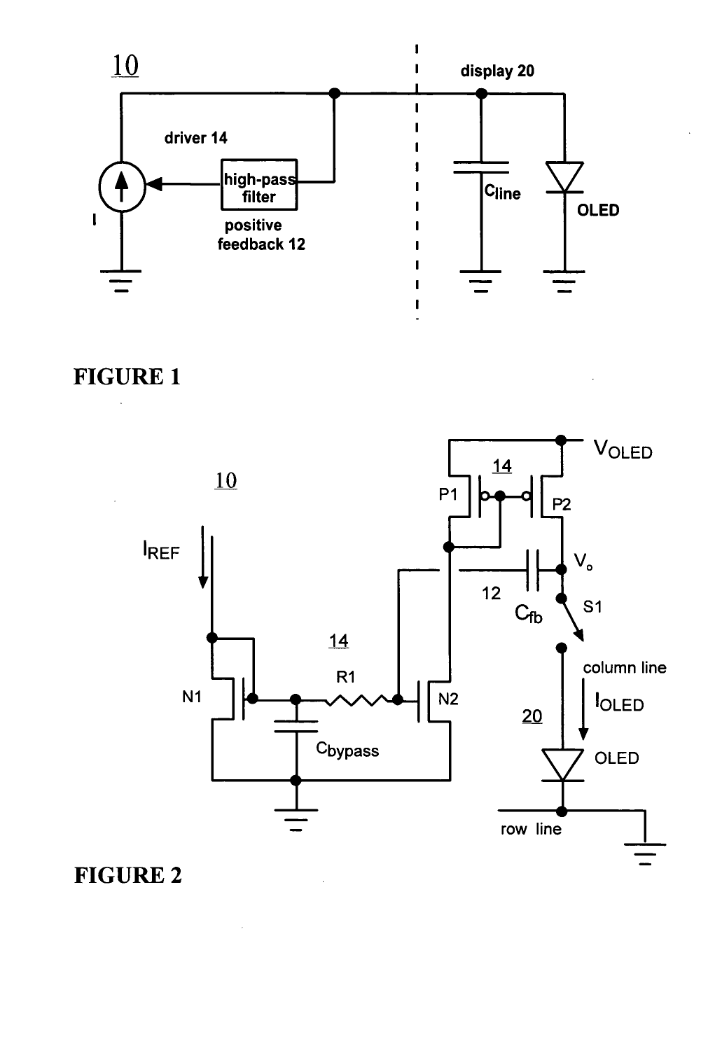

FIG. 1 is an electrical circuit schematic diagram of an example embodiment of an electronic driver circuit 10. Display 20 typically involves a large number of picture elements arranged in rows and columns and connected to electrical row and column conductors via which energizing electrical signals are applied thereto. Display 20 is represented by a capacitance Cₗᵢₙₑ in parallel with a picture element, e.g., represented by the picture element OLED. The capacitance Cₗᵢₙₑ represents the effective aggregate capacitance of the display including capacitance inherent in the elements OLED and in the electrical conductors between the driver 10 and the picture element(s) OLED, whether resulting from the display or from wiring or other sources.

A circuit 10 employing feedback 12 from the column voltage to the controllable current source 14 that generates programming currents I for the pixels of a display 20 is illustrated. The output of the current source 14 is fed to the display 20, but is also applied to the input of a high-pass filter 12 that provides positive feedback to the current source 14. As the line capacitance Cₗᵢₙₑ of display 20 is being charged, e.g., to a more positive voltage, the high-pass filter 12 feeds back a positive voltage Vₒ to the current source 14 that causes more current I to be generated, and the line capacitance Cₗᵢₙₑ charges even faster. As the OLED picture element OLED begins to turn on and the charging slows down as a result, then the magnitude of the fedback voltage drops. If the transfer function of the high-pass filter 12 is zero at DC, then the column voltage Vₒ will settle at exactly the same voltage that it would have settled to in the absence of the feedback, and so the effect of the feedback is simply to make convergence to the final voltage Vₒ value faster.

FIG. 2 is an electrical circuit schematic diagram of an example embodiment of an electronic driver circuit 10 that provides feedback 12 from the column voltage Vₒ to the current generator 14 itself.

In particular, FIG. 2 illustrates a simple approach that requires little circuitry in addition to the current source 14 itself. The controllable current source 14 for the output is implemented as a PMOS current mirror P1, P2 attached to the high-voltage V_{OLED} positive supply rail, driven by an NMOS current mirror N1, N2 which is referenced to ground. Switch S1 connects the current source to the column line of display 20 to begin charging thereof and the driving of the picture element OLED associated therewith. Switch S1 represents a commutating switch that connects the current source output Vₒ to each column conductor in turn as the display 20 is scanned to produce a displayed pattern or image, however, only one column element OLED is shown.

In a current mirror circuit, such as that provided by diode-connected NMOS transistor N1 and NMOS transistor N2, or by diode-connected PMOS transistor P1 and PMOS transistor P2, the output current that flows in the output transistor N2, P2 is a multiple of the current supplied to transistor N1, PI, wherein the multiplier is determined principally by the physical characteristics of the transistors, as is known to those of ordinary skill in the art. The multiplier or ratio of a current mirror may be unity, or may be greater or less than unity.

A current mirror may have plural output transistors, e.g., transistors N2, P2, with their gates connected in parallel to a diode-connected input transistor, e.g., N1, P1, in which case each output transistor produces a current that is a multiple of the current applied to the input transistor, wherein the multiple or ratio is determined by the physical characteristics of each output transistor in relation to that of the input transistor. In other words, the multiplier or ratio of each output transistor of a plural output transistor current mirror may be unity, or may be greater or less than unity, independently of the other output transistors thereof.

Thus, in a driver circuit 10, one diode-connected transistor N1 may receive the input current I_{REF} to produce a voltage that is applied to the gates of plural transistors N2 wherein each transistor N2 is associated with a driver (P1, P2, R1, C_{fb}) for a particular column of display 10. In such case, switch S1 is simply an on-off switch that closes at the times when input current I_{REF} corresponds to data to produce a desired response for a display element OLED in the particular column. Alternatively, one driver circuit 10 may be employed to drive plural columns in sequence, in which case switch S1 is a commutating switch that connects the display elements OLED of a particular column to driver 10 at the times when input current I_{REF} corresponds to data to produce a desired response for a display element OLED in the particular column.

Transistor N1 provides a reference bias that is shared by all outputs, all positions of switch S1 in its scanning of the column lines, and its reference current I_{ref} can be generated internally or externally by a user. Note that the gate of transistor N2 is connected to transistor N1 via resistor R1, and also is coupled through feedback 12 capacitor C_{fb} to the output Vₒ. Specifically, capacitance C_{fb} is connected between the output voltage Vo and the gate of transistor N2. The effect of the feedback 12 capacitor C_{fb} is to elevate the output current I_{OLED} while the column is charging. As the column settles towards its final level, the effect of the feedback 12 diminishes and goes away and the column settles at the proper current level I_{OLED} which is a multiple of I_{REF} determined by the multipliers of the current mirrors N1, N2 and P1, P2.

A bypass capacitor C_{bypass} is used to keep the bias voltage generated by transistor N1 at a DC level, to avoid coupling between adjacent columns. Capacitance C_{bypass} may be thought of as providing smoothing and noise reduction.

For discharging the column line, e.g., the capacitance thereof, an MOS transistor discharge switch (not shown) may be provided to selectively connect the column line to ground, or to a precharge voltage for the column line 20, in preparation for the next data current cycle. Further, provision may be made in the feedback path 12 for controlling what happens when the current source 14 is disconnected from the load, i.e. the column. An MOS transistor switch (not shown, connected in series with C_{fb}) may be utilized to open the feedback path 12 via C_{fb}, and another MOS transistor switch (not shown, connected in parallel with C_{fb}) may be utilized to discharge any residual charge on C_{fb}.

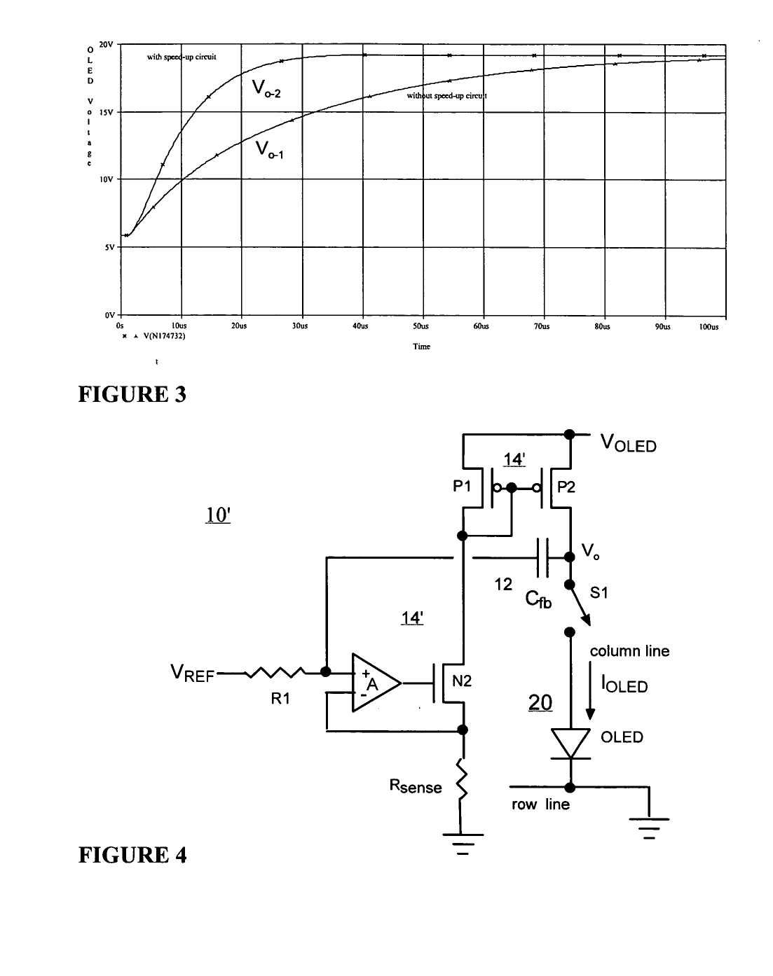

FIG. 3 is a graphical representation illustrating example voltage versus time responses for two different electronic circuits. Specifically, FIG. 3 illustrates charging characteristics obtained with the circuit of FIG. 2 and a typical PMOLED display column with a data current of 2 mA and a parasitic column capacitance of 5 nF, simulated with the circuit simulator PSPICE for two cases—one without feedback and another with feedback as described. FIG. 3 illustrates an example display scan line time of 100 usec, which corresponds to a 160-line display with a 60 Hz refresh rate. Because the OLED voltage Vₒ₋₁ without feedback requires substantially all of the 100 usec line time to reach its final level, the display would have serious convergence error and would not permit good gray-scale control. On the other hand, with feedback as described, the OLED voltage Vₒ₋₂ reach its final level in about 25-30% of the 100 usec line time so as to permit the speed-up circuit 10 of FIG. 2 to provide very good convergence and gray-scale control.

Transistors N2, P1, and P2 comprise a low-gain amplifier 14 with a dominant pole set by the column charging time-constant (which is actually not “constant” because of the nonlinear characteristic of the OLED diode). C_{fb} introduces positive feedback 12 via a network that puts a zero into the feedback path. Significant speed-up of Vₒ can be obtained without any stability problems, but ultimately, with a very large C_{fb} and/or a large R1, the output Vₒ can be made to overshoot and ring, and so circuit stability must be addressed in selecting appropriate element values. Making the feedback adjustable lets the user choose the optimum speed-up while avoiding instability.

The degree of speed-up provided by feedback 12 may be adjusted by changing the time-constant, i.e. the product of R1 times C_{fb}. The speed-up can be user-adjustable, e.g., by changing the resistance value and/or the capacitance value. For example, the capacitance C_{fb} may be provided by a circuit including four to six capacitors having binary-weighted capacitance values and a like number of series switches, e.g., with one switch in series connection with each capacitance, to allow the capacitors to be switched into and/or out of parallel connection to provide a desired total capacitance C_{fb}.

While the circuit shown in FIG. 2 is satisfactory for many applications, it typically does not provide a very “stiff” (i.e. high output impedance) current source because the output conductance of P2 is finite. That is, the difference in drain voltage between transistors P1 and P2 could lead to current mismatch between these devices (i.e. a change or non-linearity in the current ratio or multiplier exhibited by P1, P2 as a current mirror), however, transistors P1 and P2 could be cascoded with one or more additional PMOS transistors to increase their effective output impedance.

Similarly, transistors N1, N2 may also have different drain voltages with like effect as described in relation to transistors P1, P2. Not only can these two devices N1 and N2 have different drain voltages, causing mismatched currents, but they can also be widely separated on the chip and therefore suffer from device parameter mismatch, e.g., because transistor N1 is a bias generator that will typically provide bias voltage for many output current generators (i.e. many transistors N2). This is not true of transistors P1 and P2, of which a set are provided for each column of display 20 and so transistors P1, P2 of each set can be close together and therefore will not suffer from variations in device parameters resulting from physical separation on an integrated circuit chip.

FIG. 4 is an electrical circuit schematic diagram of an example embodiment of an electronic driver circuit 10′ that provides feedback 12 from the column voltage Vₒ to the current generator 14′ itself. The effects of both of the foregoing—drain voltage mismatch and parameter mismatch—are diminished or avoided in the circuit illustrated in FIG. 4.

Therein each output circuit 14′ includes an operational amplifier A in addition to transistor N2. Amplifier A is arranged as a “unity follower” including transistor N2 to produce a current in transistor N2 that is directly related to the input voltage V_{REF} in the steady state. Resistor Rₛₑₙₛₑ is utilized to sense the current through transistor N2 and to feedback to the input of amplifier A a signal related thereto to ensure that the voltage applied to the gate of N2 is just right for producing a DC or steady state current through N2 and P1 having the value of the ratio V_{REF}/Rₛₑₙₛₑ.

Because voltage V_{REF} can be externally applied, it is the same for all output circuits 14′ that are connected in parallel to receive it. It is generally true in integrated circuit processes that resistances (in this case, the resistors Rₛₑₙₛₑ for each of the outputs) can be matched across a chip to greater precision than can parameters of transistors, and the matching thereof typically obtainable is typically satisfactory for matching the output currents produced by various ones of circuits 14 responsive to the drive voltage V_{REF}. Thus the currents through transistors P1 and P2 over all of the columns of a display 20 can be matched satisfactorily.

Feedback circuit 12 operates on circuit 14′ in the same way as described above in relation to circuit 14 of FIGS. 2 and 3 with the high-pass filter R1-C_{fb} providing positive feedback 12 to input of circuit 14′, here at the input of operational amplifier A. Specifically, capacitance C_{fb} is connected between the output voltage Vo and the non-inverting input of operational amplifier A. Thus, the current I_{OLED} is dynamically increased as the column line charges more quickly towards the desired output voltage Vₒ.

One prior art approach to the column charging problem devotes part of each line time to a column-voltage precharge interval. This requires that an estimate be made of the proper starting voltage for column charging, and that the columns to be reset (pre-charged) to this voltage before switching over to the driving current sources. While this prior art approach is somewhat faster than charging each column from zero volts for each line, the reset voltage must be lower than the lowest data voltage that can turn on a pixel, and as a result the required voltage swing can still be many volts. The circuits of FIGS. 2 and 4 advantageously speed up the charging cycle itself and, for further speed-up, can be combined with a precharge interval, during which the column is reset to a voltage level that is less than the lowest data voltage.

An electronic driver circuit 10, 10′ for driving a load 20, wherein the load 20 exhibits a capacitance Cₗᵢₙₑ, comprises a source of an input data signal I_{REF}, V_{REF}, a controllable current source 14, 14′ having an input coupled for receiving the input data signal I_{REF}, V_{REF}, for providing at output Vₒ an output current I_{OLED} proportionally related in steady-state value to the input data signal I_{REF}, V_{REF}. Capacitance C_{fb} is coupled between the output of controllable current source 14, 14′ and the input thereof for providing positive feedback 12 from the output to the input of controllable current source 14, 14′.

The input data signal may be a current I_{REF}, wherein controllable current source 14 includes diode-connected transistor N1 for providing an input voltage signal responsive to the input data signal current I_{REF}. The input data signal may be a voltage V_{REF}, wherein the controllable current source 14′ includes an amplifier A coupled to a resistance Rₛₑₙₛₑ for providing a current proportional to the input data signal voltage V_{REF}, and the resistance Rₛₑₙₛₑ. A resistance R₁ couples the source to the input of controllable current source 14, 14′ for reacting with capacitance C_{fb} for providing positive feedback 12.

Controllable current source 14, 14′ may comprise a first transistor N2 of a first polarity having a controllable conduction path and a control electrode for controlling the conduction of its controllable conduction path, wherein input data signal I_{REF}, V_{REF}, is applied to the control electrode of first transistor N2. Second and third transistors P1, P2 are of a second polarity opposite to the first polarity and each of second and third transistors P1, P2 has a controllable conduction path and a control electrode for controlling the conduction of its controllable conduction path. The control electrodes of second and third transistors P1, P2 are connected to each other, to one end of the controllable conduction path of first transistor N2, and to one end of the controllable conduction path of second transistor P1, wherein the steady-state output current produced at the controllable conduction path of third transistor P2 is proportionally related to the input data signal I_{REF}, V_{REF}.

An electronic driver circuit 10 for driving a load 20, wherein the load 20 exhibits a capacitance Cₗᵢₙₑ, comprises a source of an input data signal current I_{REF}, and a diode-connected transistor N1 of a first polarity for providing an input voltage signal responsive to the input data signal current I_{REF}. A second transistor N2 of the first polarity has a controllable conduction path and a control electrode for controlling the conduction of its controllable conduction path, wherein the input voltage signal provided by diode-connected transistor N1 is applied between the control electrode and one end of the controllable conduction path of second transistor N2. Third and fourth transistors P1, P2 are of a second polarity opposite to the first polarity and each of third and fourth transistors P1, P2 has a controllable conduction path and a control electrode for controlling the conduction of its controllable conduction path, wherein one end of the controllable conduction paths of third and fourth transistors P1, P2 are connected together. The control electrodes of third and fourth transistors P1, P2 are connected to each other, and to the other end of the controllable conduction path of second transistor N2. A capacitance C_{fb} is coupled between the other end of the controllable conduction path of fourth transistor P2 and the control electrode of second transistor N2 for providing positive feedback 12 thereat. A resistance R₁ couples source I_{REF} to the control electrode of second transistor N2 for reacting with capacitance C_{fb} for providing positive feedback 12. The steady-state output current I_{OLED} produced at the other end of the controllable conduction path of fourth transistor P2 is proportionally related to the input data signal current I_{REF}.

An electronic driver circuit 14′ for driving a load 20, wherein the load 20 exhibits a capacitance Cₗᵢₙₑ, comprises a source of an input data signal voltage V_{REF}, an amplifier A coupled to a first resistance Rₛₑₙₛₑ for providing a current proportional to input data signal voltage V_{REF} and resistance Rₛₑₙₛₑ. First and second transistors P1, P2 of a first polarity each have a controllable conduction path and a control electrode for controlling the conduction of its controllable conduction path, wherein one end of the controllable conduction paths of first and second transistors P1,P2 are connected together. The control electrodes of first and second transistors P1,P2 are connected to each other and to the other end of the controllable conduction path of first transistor P1 for receiving the current provided by amplifier A. A capacitance C_{fb} is coupled between the other end of the controllable conduction path of second transistor P2 and an input of amplifier A for providing positive feedback 12 thereat. A second resistance R₁ couples the source to the input of amplifier A for reacting with capacitance C_{fb} for providing positive feedback 12. The steady-state output current I_{OLED} produced at the other end of the controllable conduction path of second transistor P2 is proportionally related to the input data signal voltage V_{REF}.

Electronic driver circuit 14′ may further comprise a third transistor N2 of second polarity opposite to the first polarity and having a controllable conduction path and a control electrode for controlling the conduction of its controllable conduction path. The control electrode of third transistor N2 is connected to an output of amplifier A, one end of the controllable conduction path of third transistor N2 is connected to first resistance Rₛₑₙₛₑ and the other end of the controllable conduction path thereof is connected to the control electrode of first transistor P1.

As used herein, the term “about” means that dimensions, sizes, formulations, parameters, shapes and other quantities and characteristics are not and need not be exact, but may be approximate and/or larger or smaller, as desired, reflecting tolerances, conversion factors, rounding off, measurement error and the like, and other factors known to those of skill in the art. In general, a dimension, size, formulation, parameter, shape or other quantity or characteristic is “about” or “approximate” whether or not expressly stated to be such.

Further, what is stated as being “optimum” or “deemed optimum” may or not be a true optimum condition, but is the condition deemed to be “optimum” by virtue of its being selected in accordance with the decision rules and/or criteria defined by the applicable controlling function, e.g., the selected RC time constant for feedback circuit 12 may be limited by the capacitance values obtainable given the number and values of the capacitances that can be switched in parallel.

While the present invention has been described in terms of the foregoing example embodiments, variations within the scope and spirit of the present invention as defined by the claims following will be apparent to those skilled in the art. For example, circuits of opposite polarity to those illustrated may be provided where the input current mirror (illustrated with N1, N2) includes PMOS transistors and where the output current mirror (illustrated with P1, P2) includes NMOS transistors.

Amplifier A may be an operational amplifier, i.e. an amplifier having a very high forward gain, or may be another amplifier having a lesser gain. Further, amplifier A may have differential inputs as illustrated or may have only one input.

Finally, numerical values stated are typical or example values, and are not limiting values. For example, the 2 mA drive current may be a greater or lesser value, and the arrangements described may be utilized with displays having different line scan times and different numbers of lines than those set forth herein. The terms proportional and proportionally related herein include direct proportionality and/or inverse proportionality.

1. An electronic driver circuit for driving a load, wherein the load exhibits a capacitance, comprising:
a source of an input data signal;
a controllable current source having an input coupled for receiving the input data signal for providing at an output thereof an output current proportionally related in steady-state value to the input data signal; and
a capacitance coupled between the output of said controllable current source and the input thereof for providing positive feedback from the output to the input of said controllable current source.

2. The electronic driver circuit of claim 1 wherein the input data signal is a current and wherein said controllable current source includes a diode-connected transistor for providing an input voltage signal responsive to the input data signal current.

3. The electronic driver circuit of claim 1 wherein the input data signal is a voltage and wherein said controllable current source includes an amplifier coupled to a resistance for providing a current proportional to the input data signal voltage and the resistance.

4. The electronic driver circuit of claim 1 further comprising a resistance coupling said source to the input of said controllable current source for reacting with said capacitance for providing said positive feedback.

5. The electronic driver circuit of claim 1 wherein said controllable current source comprises:
a first transistor of a first polarity having a controllable conduction path and a control electrode for controlling the conduction of said controllable conduction path, wherein the input data signal is applied to the control electrode of said first transistor;
second and third transistors of a second polarity opposite to the first polarity, each of said second and third transistors having a controllable conduction path and a control electrode for controlling the conduction of said controllable conduction path,
wherein the control electrode of said second and third transistors are connected to each other, to one end of the controllable conduction path of said first transistor; and to one end of the controllable conduction path of said second transistor;
wherein the steady-state output current produced at the controllable conduction path of said third transistor is proportionally related to the input data signal.

6. An electronic driver circuit for driving a load, wherein the load exhibits a capacitance, comprising:
a source of an input data signal current;
a controllable current source having an input coupled for receiving the input data signal current for providing at an output thereof an output current proportionally related in steady state value to the input data signal current; and
a capacitance coupled between the output of said controllable current source and the input thereof for providing positive feedback from the output to the input of said controllable current source.

7. The electronic driver circuit of claim 6 wherein said controllable current source includes a diode-connected transistor for providing an input voltage signal responsive to the input data signal current.

8. The electronic driver circuit of claim 6 further comprising a resistance coupling said source to the input of said controllable current source for reacting with said capacitance for providing said positive feedback.

9. The electronic driver circuit of claim 6 wherein said controllable current source comprises:
a first transistor of a first polarity having a controllable conduction path and a control electrode for controlling the conduction of said controllable conduction path, wherein the input data signal current is applied to the control electrode of said first transistor;
second and third transistors of a second polarity opposite to the first polarity, each of said second and third transistors having a controllable conduction path and a control electrode for controlling the conduction of said controllable conduction path,
wherein the control electrodes of said second and third transistors are connected to each other, to one end of the controllable conduction path of said first transistor; and to one end of the controllable conduction path of said second transistor;
wherein the output current produced at the controllable conduction path of said third transistor is proportionally related to the input data signal current.

10. An electronic driver circuit for driving a load, wherein the load exhibits a capacitance, comprising:
a source of an input data signal voltage;
a controllable current source having an input coupled for receiving the input data signal voltage for providing at an output thereof an output current proportionally related in steady-state value to the input data signal voltage; and
a capacitance coupled between the output of said controllable current source and the input thereof for providing positive feedback from the output to the input of said controllable current source.

11. The electronic driver circuit of claim 10 wherein said controllable current source includes an amplifier coupled to a resistance for providing a current proportional to the input data signal voltage and the resistance.

12. The electronic driver circuit of claim 11 wherein said controllable current source further comprises:
a first transistor of a first polarity having a controllable conduction path and a control electrode for controlling the conduction of said controllable conduction path, wherein the control electrode of said first transistor is connected to an output of said amplifier;
second and third transistors of a second polarity opposite to the first polarity, each of said second and third transistors having a controllable conduction path and a control electrode for controlling the conduction of said controllable conduction path, wherein one end of the controllable conduction paths of said second and third transistors are connected together;
wherein the control electrodes of said second and third transistors are connected to each other, to one end of the controllable conduction path of said first transistor, and to the other end of the controllable conduction path of said second transistor;
wherein the steady-state output current produced at the controllable conduction path of said third transistor is proportionally related to the input data signal voltage.

13. The electronic driver circuit of claim 10 further comprising a resistance coupling said source to the input of said controllable current source for reacting with said capacitance for providing said positive feedback.

14. An electronic driver circuit for driving a load, wherein the load exhibits a capacitance, comprising:
a source of an input data signal current;
a diode-connected transistor of a first polarity for providing an input voltage signal responsive to the input data signal current;
a second transistor of the first polarity having a controllable conduction path and a control electrode for controlling the conduction of said controllable conduction path, wherein the input voltage signal provided by said diode-connected transistor is applied between the control electrode and one end of the controllable conduction path of said second transistor;
third and fourth transistors of a second polarity opposite to the first polarity, each of said third and fourth transistors having a controllable conduction path and a control electrode for controlling the conduction of said controllable conduction path, wherein one end of the controllable conduction paths of said third and fourth transistors are connected together;
wherein the control electrodes of said third and fourth transistors are connected to each other, and to the other end of the controllable conduction path of said second transistor;
a capacitance coupled between the other end of the controllable conduction path of said fourth transistor and the control electrode of said second transistor for providing positive feedback thereat; and
a resistance coupling said source to the control electrode of said second transistor for reacting with said capacitance for providing said positive feedback,
wherein the steady-state output current produced at the other end of the controllable conduction path of said fourth transistor is proportionally related to the input data signal current.

15. An electronic driver circuit for driving a load, wherein the load exhibits a capacitance, comprising:
a source of an input data signal voltage
an amplifier coupled to a first resistance for providing a current proportional to the input data signal voltage and the resistance;
first and second transistors of a first polarity, each of said first and second transistors having a controllable conduction path and a control electrode for controlling the conduction of said controllable conduction path, wherein one end of the controllable conduction paths of said first and second transistors are connected together;
wherein the control electrodes of said first and second transistors are connected to each other and to the other end of the controllable conduction path of said first transistor for receiving the current provided by said amplifier;
a capacitance coupled between the other end of the controllable conduction path of said second transistor and an input of said amplifier for providing positive feedback thereat; and
a second resistance coupling said source to the input of said amplifier for reacting with said capacitance for providing said positive feedback,
wherein the steady-state output current produced at the other end of the controllable conduction path of said second transistor is proportionally related to the input data signal voltage.

16. The electronic driver circuit of claim 15 further comprising a third transistor of second polarity opposite to the first polarity and having a controllable conduction path and a control electrode for controlling the conduction of said controllable conduction path, wherein the control electrode of said third transistor is connected to an output of said amplifier, one end of the controllable conduction path of said third transistor is connected to said first resistance, and the other end of the controllable conduction path thereof is connected to the control electrode of said first transistor for providing the current provided by said amplifier.
